(19) United States
(12) Patent Application Publication
(10) Pub. No.: US 2014/0138141 A1
(43) Pub. Date: May 22, 2014

(54) PERIPHERAL CIRCUIT STRUCTURE

(71) Applicants: Chung-Hsien Li, Taichung City (TW); Kuo-Hsing Chen, New Taipei City (TW); Yu-Ting Chen, Taoyuan County (TW); Chen-Hao Su, Taichung City (TW)

(72) Inventors: Chung-Hsien Li, Taichung City (TW); Kuo-Hsing Chen, New Taipei City (TW); Yu-Ting Chen, Taoyuan County (TW); Chen-Hao Su, Taichung City (TW)

(73) Assignee: WINTEK CORPORATION, Taichung City (TW)

(21) Appl. No.: 14/086,970

(22) Filed: Nov. 22, 2013

(30) Foreign Application Priority Data
Nov. 22, 2012 (TW) 101143709

(51) Int. Cl. H05K 1/02

(52) U.S. Cl. CPC H05K 1/0213
USPC 174/261

(57) ABSTRACT

A peripheral circuit structure disposed on a substrate having an element region and a peripheral circuit region is provided. The peripheral circuit structure located in the peripheral circuit region includes first pads, second pads, a first trace, a second trace and third traces connected to the second pads and a device located in the element region. The first pads include a first ground pad and a second ground pad. The second pads are located between the first ground pad and the second ground pad. Two ends of the first trace are respectively electrically connected to the first ground pad and the second ground pad. Two ends of the second trace are respectively electrically connected to the first ground pad and the second ground pad, so that the second trace, the first trace, the first ground pad and the second ground form a closed loop.

### CROSS-REFERENCE TO RELATED APPLICATION

This application claims the priority benefit of Taiwan application serial no. 101143709, filed on Nov. 22, 2012. The entirety of the above-mentioned patent application is hereby incorporated by reference herein and made a part of this specification.

### BACKGROUND

1. Field of the Invention

The present invention is directed to a peripheral circuit structure and more particularly, to a peripheral circuit structure contributing to improving the capability for resisting electrostatic discharge (ESD).

2. Description of Related Art

Generally, damages caused by the electrostatic discharge (ESD) possibly happen to an electronic product at any time when being manufactured, packaged, tested, delivered, even finally shipped and used, which leads to high risk of malfunction. Thus, the electronic product has to be designed with an ESD protection capability for prolonging the lifespan of the electronic product.

In a manufacturing process of the electronic product, it is common to manufacture an ESD protection circuit around the device so as to transmit currents produced by the ESD via ground pads to the external and prevent the peripheral circuit structure from being damaged by the currents flowing to the internal circuits.

The ESD protection circuit is typically composed of metal traces and metal oxide pads connected with each other. The metal traces contribute to improving the conductivity of the peripheral circuits while the connection with the ground pads contributes to avoiding the oxidation of the metal traces. However, the traces and the pads have different resistances, such that once an instantaneous current fails to rapidly passes through where the traces and the pads are connected, a current crowd effect occurs and the peripheral circuit structure is easily damaged by the ESD. Specifically, the connection portion of the traces correspondingly in connection with the ground pads which are used as the ESD protection circuit is more easily damaged by the ESD. Thus, the connection portion of the traces and the corresponding ground pads require to be further designed for effectively transmitting the currents probably accumulated at the connection portion and improving the capability of the peripheral circuit structure for resisting the ESD.

### SUMMARY

The present invention is directed to a peripheral circuit structure contributing to draining out currents accumulated where traces and ground pads are connected.

The present invention is directed to a peripheral circuit structure disposed on a substrate. The substrate includes an element region and a peripheral circuit region surrounding the element region. The peripheral circuit structure is disposed in the peripheral circuit region, and a plurality of elements are disposed in the element region. The peripheral circuit structure includes a plurality of first pads, a plurality of second pads, a first trace, a second trace and a plurality of third traces. The first pads includes a first ground pad and a second ground pad. The second pads are located between the first ground pad and the second ground pad. The first trace is disposed around the element region, and two ends of the first trace are electrically connected with the first ground pad and the second ground pad respectively. The second trace is located at a side of each second pad, which is away from the element region, and two ends of the second trace are electrically connected with the first ground pad and the second ground pad respectively, such that a closed loop is formed by the second trace, the first trace, the first ground pad and the second ground pad. The third traces are connected with the elements disposed in the element region, electrically connected with the second pads and located in the region demarcated by the closed loop.

In an embodiment of the present invention, the first trace and the second trace are respectively connected with two opposite ends of the first ground pad.

In an embodiment of the present invention, the first trace and the second trace are respectively connected with two opposite ends of the second ground pad.

In an embodiment of the present invention, the peripheral circuit structure further includes a fourth trace connected between the first trace and the second trace.

In an embodiment of the present invention, both the first trace and the second trace are connected with one end of the first ground pad, and the end is away from the element region.

In an embodiment of the present invention, both the first trace and the second trace are connected with one end of the second ground pad, and the end is away from the element region.

In an embodiment of the present invention, the first pads further include a third ground pad located between the first ground pad and the second ground pad, and the second trace is further connected with the third ground pad.

In an embodiment of the present invention, the first trace and the second trace extend from the substrate to a top of one of the first pads and further cover a side wall of the one of the first pads.

In an embodiment of the present invention, at least one of the third traces extends from the substrate to a top of one of the second pads, and further covers a side wall of the one of the second pads.

In an embodiment of the present invention, the first trace and the second trace respectively extend to a place between the substrate and one of the first pads, at least one of the third traces extends to a place between the substrate and one of the second pads, and lengths for the first trace and the second trace respectively extending to the place between the substrate and the one of the first pads are larger than a length for the at least one of the third traces extending to the place between the substrate and the one of the second pads.

In an embodiment of the present invention, the peripheral circuit structure further includes an insulation layer. The insulation layer at least covers the first trace, the second trace and the third traces and has a plurality of openings exposing a partial area of each first pad and a partial area of each second pad, respectively.

In an embodiment of the present invention, the elements disposed in the element region include touch sensing elements or display elements.

In an embodiment of the present invention, when the first trace is connected with one end of one of the first pads, which is away from the element region, the peripheral circuit structure further includes a peripheral element located between the first trace and at least one of the third traces.

The present invention is directed to a peripheral circuit structure disposed on a substrate. The substrate includes an element region and a peripheral circuit region surrounding the element region. The peripheral circuit structure is disposed in the peripheral circuit region, and a plurality of elements are disposed in the element region. The peripheral circuit structure includes a plurality of first pads, a plurality of second pads, a first trace, a second trace and a plurality of third traces. The first pads includes a first ground pad, a second ground pad and at least one third ground pad located between the first ground pad and the second ground pad. The second pads are located between the first ground pad and the second ground pad. The first trace is disposed around the element region. Two ends of the first trace are electrically connected with the first ground pad and the second ground pad respectively. The second trace is located at a side of the second pads, which is away from the element region. One end of the second trace is connected with the at least one third ground pad, and the other end of the second trace is connected with one of the first ground pad and the second ground pad. The third traces are connected with the devices disposed in the element region and electrically connected with the second pads.

Accordingly, in the present invention, the traces (including the first trace and the second trace) and the ground pads (including the first ground pad and the second ground pad) which are electrically connected with each other contributes to increasing paths of currents flowing through where the traces and the ground pads are connected and effectively transmitting out the currents accumulated where the traces and the ground pads are connected, such that the capability of the peripheral circuit structure for resisting electrostatic discharge (ESD) may be improved, and reliability of an integrated circuit (IC), a display panel or a touch panel applying the peripheral circuit structure may be improved.

In order to make the aforementioned and other features and advantages of the present invention more comprehensible, several embodiments accompanied with figures are described in detail below.

### BRIEF DESCRIPTION OF THE DRAWINGS

The accompanying drawings are included to provide a further understanding of the present invention, and are incorporated in and constitute a part of this specification. The drawings illustrate embodiments of the present invention and, together with the description, serve to explain the principles of the present invention.

FIG. 1 through FIG. 6 are schematic top views illustrating a touch panel applying peripheral circuit structures according to different embodiments of the present invention.

FIG. 7A through FIG. 7D illustrate four types of connection modes of traces and pads.

FIG. 8 is a partial schematic top view illustrating a peripheral circuit structure according to an embodiment of the present invention.

FIG. 9A is a partial schematic side view illustrating a peripheral circuit structure according to another embodiment of the present invention.

FIG. 9B is a partial schematic side view illustrating a peripheral circuit structure according to still another embodiment of the present invention.

### DESCRIPTION OF EMBODIMENTS

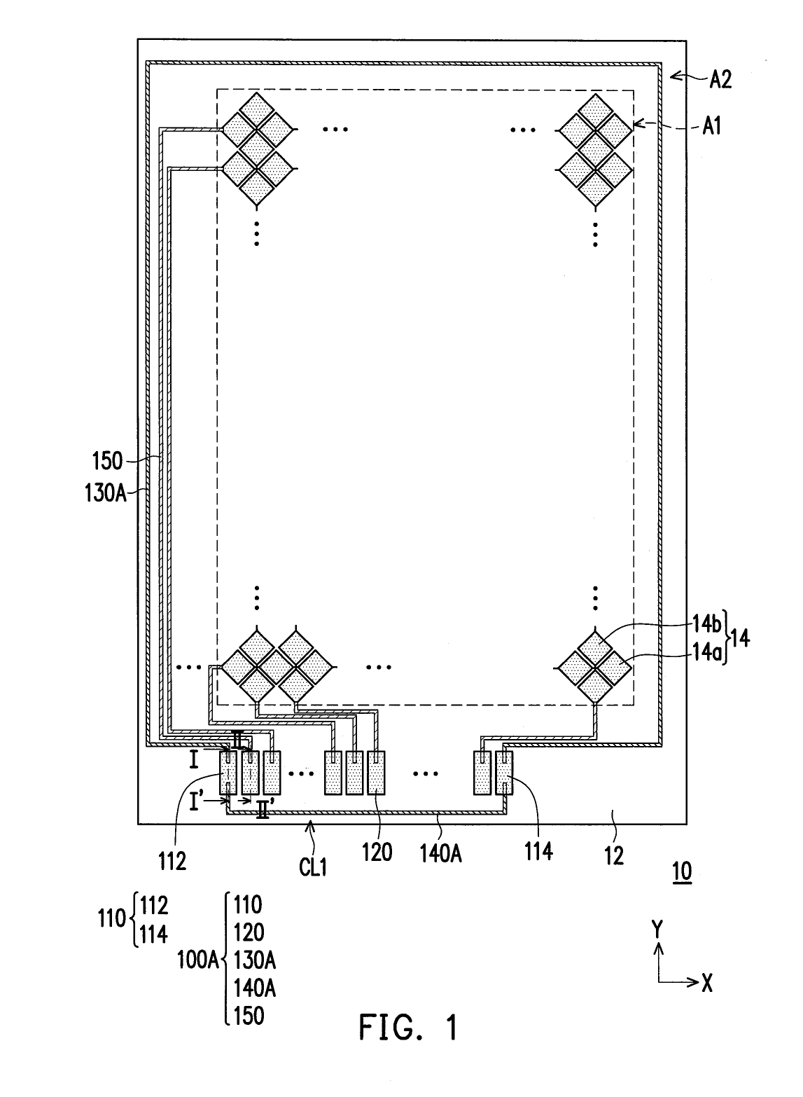

FIG. 1 through FIG. 6 are schematic top views illustrating a touch panel applying peripheral circuit structures according to different embodiments of the present invention. Referring to FIG. 1, a peripheral circuit structure 100A of the present embodiment may be applied in a touch panel 10, for example, wherein the touch panel 10 includes a substrate 12. In the present embodiment, the peripheral circuit structure 100A is disposed on the substrate 12.

In detail, the substrate 12 includes an element region A1 and a peripheral circuit region A2 surrounding the element region A1. The peripheral circuit structure 100A is disposed in the peripheral circuit region A2, and at least one element 14 is disposed in the element region A1.

In the present embodiment, the device 14 is, for example, a touch sensing element, and a plurality of touch sensing elements are arranged in an array in the element region A1. A decoration layer is disposed on the peripheral circuit region A2 to shield the peripheral circuit structure. For example, as a touch sensing device, the elements 14 may include a first sensing string 14a and a second sensing string 14b. The first sensing string 14a extends along a first direction X and is arranged along a second direction Y, while the second sensing string 14b extends along the second direction Y and is arranged along the first direction X. In the present embodiment, the first direction X is perpendicular to the second direction Y, for example. Certainly, the aforementioned implementation manner is only an example for illustration and the present invention is not limited thereto.

In other embodiments that are not shown, the first direction X is not necessarily perpendicular to the second direction Y. Otherwise, the elements 14 may be another type of touch sensing element, such as a single-layer sensing electrode without a bridge structure which is a structure of interlacing multiple conductive lines. When the peripheral circuit structure 100A is applied in a display panel, the elements 14 may be a thin-film transistor array for driving display medium or a display device array, such as an organic light-emitting diodes array. In summary, any element disposed on the substrate 12 for providing specific functions, such as light-emitting, displaying, touch sensing, light sensing and so forth, may be considered as the elements 14.

The peripheral circuit structure 100A includes a plurality of first pads 110, a plurality of second pads 120, a first trace 130A, a second trace 140A and a plurality of third traces 150. The first pads 110 includes a first ground pad 112 and a second ground pad 114. The aforementioned ground pads are all referred in general to pads that are electrically connected to a ground potential.

The first pads 110 and the second pads 120 are electrically insulated from each other. The second pads 120 are located between the first ground pad 112 and the second ground pad 114. The first pads 110 and the second pads 120 are arranged along the first direction X; however, the present embodiment is not intent to specifically limit the arrangement manner of the pads.

The first trace 130A is disposed around the element region A1, and two ends of the first trace 130A are electrically connected with the first ground pad 112 and the second ground pad 114 respectively. The electrical connection mode as described above may include the first trace 130A partially overlapping and contacting the first pads 110.

The second trace 140A is located at a side of the second pads 120, which is away from the element region A1, and two ends of the second trace 140A are electrically connected with the first ground pad 112 and the second ground pad 114 respectively. Namely, both the first ground pad 112 and the second ground pad 114 are connected with the first trace 130A and the second trace 140A.

One end of one of the third traces 150 is electrically connected with one of the second pads 120, while the other end of the one of the third traces 150 is connected to the element 14 disposed in the element region A1. When the element 14 is a string of touch sensing medium, the first trace 130A may be connected to a terminal portion of one of the first sensing strings 14a or to a terminal portion of one of the second sensing strings 14b. At this time, the third traces 150 are all located between the first trace 130A and the element region A1, i.e. located in an area surrounded/demarcated by the first trace 130A.

A material of the first trace 130A, the second trace 140A and the third traces 150 includes metal or metal alloy with good conductivity, and a material of the first pads 110 and the second pads 120 includes metal oxide for having high resistance for oxidation. In an embodiment, in order to allow the element region A1 to have light transmittance and under the consideration that the first pads 110 and the second pads 120 may be manufactured simultaneously with the first sensing string 14a or the second sensing string 14b, the material of the first pads 110 and the second pads 120 may be the same as the material of the first sensing string 14a and the second sensing string 14b of the touch sensing device. However, the present invention is not limited thereto. In other embodiments, the first sensing string 14a and the second sensing string 14b may be made of various types of material without being limited to being only made of the light-transmissive conductive material. For example, the first sensing string 14a or the second sensing string 14b may be made of metal mesh material or partially made of metal material and further partially made of the light-transmissive conductive material, such as a ITO/Ag/ITO stacked layer structure.

Referring to FIG. 1, a closed loop CL1 is formed by the second trace 140A, the first trace 130A, the first ground pad 112 and the second ground pad 114. Namely, the first ground pad 112 and the second ground pad 114 are electrically connected with each other via the first trace 130A and/or the second trace 140A, such that a closed loop path, i.e. the closed loop CL1, is formed by the first ground pad 112, the second ground pad 114, the first trace 130A and the second trace 140A. As such, the third traces 150, the second pads 120 and the elements 14 are ringed inside the closed loop CL1 used as an electrostatic discharge (ESD) protection circuit, and therein, the second pads 120 and the elements 14 are electrically connected with the third traces 150. Thereby, damages resulted from the ESD may be prevented.

In the present embodiment, the first ground pad 112 and the second ground pad 114 are electrically connected with not only the first trace 130A but also the second trace 140A. With the increase of the amount of the traces electrically with the first ground pad 112 and the second ground pad 114, paths of currents flowing through the first ground pad 112 and the second ground pad 114 may be increased, and the currents accumulated on the first ground pad 112 (or the second ground pad 114) may be transmitted out through the first trace 130A and the second trace 140A. Accordingly, the configuration of the present embodiment contributes to improving the capability of the peripheral circuit structure 100A for resisting the damages caused by the ESD effect, such that the reliability of an IC, a display panel or a touch panel applying the peripheral circuit structure 100A may be improved.

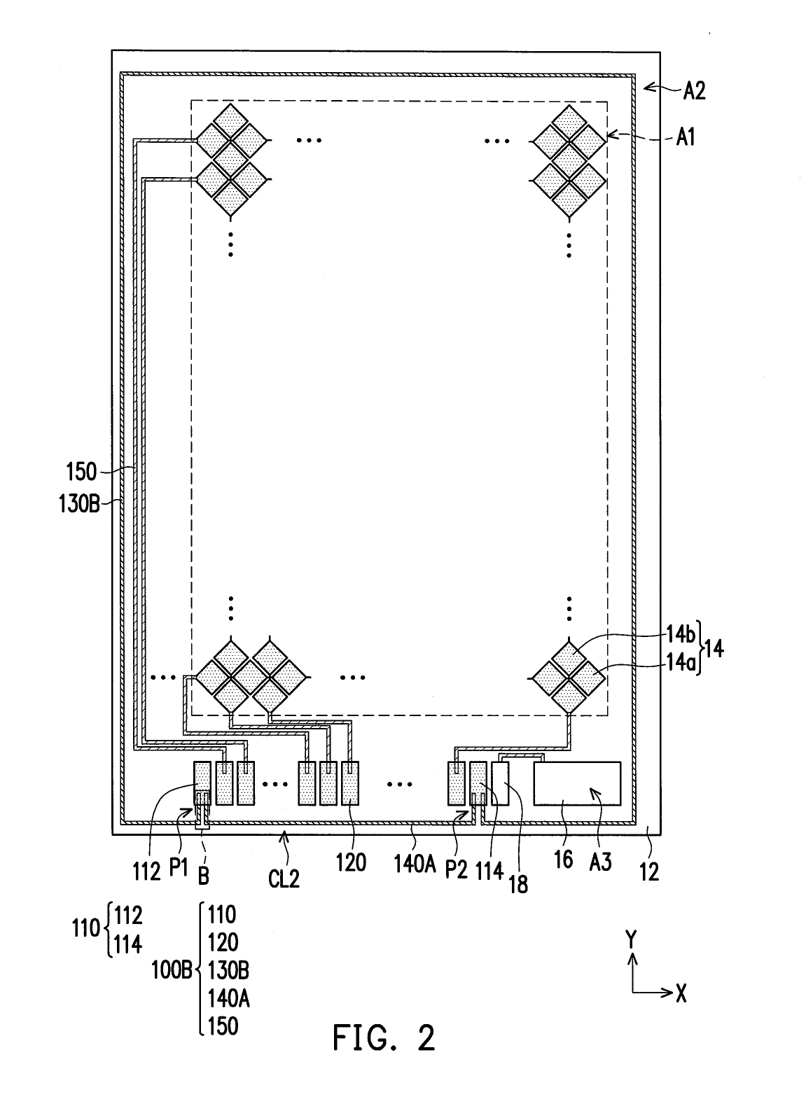

In the present embodiment, the first trace 130A and the second trace 140A are respectively connected with two opposite ends of the first ground pad 112 and are respectively connected with two opposite ends of the second ground pad 114. However, the present invention is not intent to limit the configuration relationship between the first trace 130A and the second trace 140A relative to the first ground pad 112 and/or the second ground pad 114. Other implementation embodiments of the peripheral circuit structure will be illustrated with reference to FIG. 2 through FIG. 4A. Referring to FIG. 2, a peripheral circuit structure 100B of the present embodiment has a structure similar to the peripheral circuit structure 100A of FIG. 1, and the difference between the two embodiments mainly lies in that both a first trace 130B and a second trace 140A of the peripheral circuit structure 100B of the present embodiment are likewise connected with one end of the first ground pad 112 and with one end of the second ground pad 114, and both the ends are away from the element region A1. Namely, both the first trace 130B and the second trace 140A are connected with one end P1 of the first ground pad 112 and one end P2 of the second ground pad 114, which are adjacent to a margin of the substrate 12.

Thus, a closed loop CL2 is formed by the first trace 130B, the second trace 140A, the first ground pad 112 and the second ground pad 114, and the third traces 150, second pads 120 and the device 14 are ringed by the closed loop CL2 used as an ESD protection circuit and therein, the second pads 120 and the elements 14 are electrically connected with the third traces 150. Thus, damages resulted from the ESD may be prevented. Here, the first trace 130B and the second trace 140A may be two individual conductor wires and respectively connected with the first ground pad 112 and the second ground pad 114. However, in other embodiments, the first trace 130B and the second trace 140A may be connected with each other in advance and then, connected with the first ground pad 112 and the second ground pad 114 through the same conductor wire. Namely, the two conductor wires shown in an area B may be connected as one.

In the present embodiment, currents accumulated on the first ground pad 112 (or the second ground pad 114) may be transmitted through the first trace 130A and the second trace 140A. By increasing paths of the currents flowing through the first ground pad 112 and the second ground pad 114 in the present embodiment, the currents accumulated where the ground pads and the traces are connected may be drained out more easily. Thus, the capability of the peripheral circuit structure 100B for resisting the ESD may be improved, such that the reliability of an IC, a display panel or a touch panel applying the peripheral circuit structure 100B may be improved.

Further, in the configuration of the present embodiment, both the first trace 130B and the second trace 140A are connected with the end P1 and the end P2 of the first pads 110 which are away from the element region A1. Thus, in the peripheral circuit region A2, a peripheral element 16 may be selectively disposed in an area A3 between the first trace 130B and one of the third traces 150. Here, the peripheral element 16 may be a display element displaying a specific pattern, a touch sensing element used as a shortcut key or an area providing a specific function. In such configuration, the peripheral element 16 is also surrounded by the first trace 130A so that the first trace 130B may also provide a function of resisting the ESD for the peripheral element 16. Further, when the peripheral element 16 is disposed in the area A3, the peripheral circuit structure 100B may further include a third pad 18 connected to the peripheral element 16, and the third pad 18 is located at a side of the first pads 110, which is away from the second pads 120. Moreover, in other embodiments that are not shown, the third pad 18 may be disposed between the first pads 110 and the second pads 120. Thus, the capability of the peripheral circuit structure 100B for resisting the ESD may be further improved by the second trace 140A connected between the first ground pad 112 and the second ground pad 114 that for example, the third pad 18 may be prevented from being damaged by the electrostatic.

It is to be mentioned that in FIG. 1 and FIG. 2, the two implementation embodiments of the peripheral circuit structure are only examples for illustration, and the present invention is not limited thereto. In other embodiments that are not shown, the first trace and the second trace may be connected with two opposite ends of the first ground pad, while the first trace and the second trace may be connected with the same end of the second ground pad. Or otherwise, the first trace and the second trace may be connected with the same end of the first ground pad, while the first trace and the second trace may be connected with two opposite ends of the second ground pad.

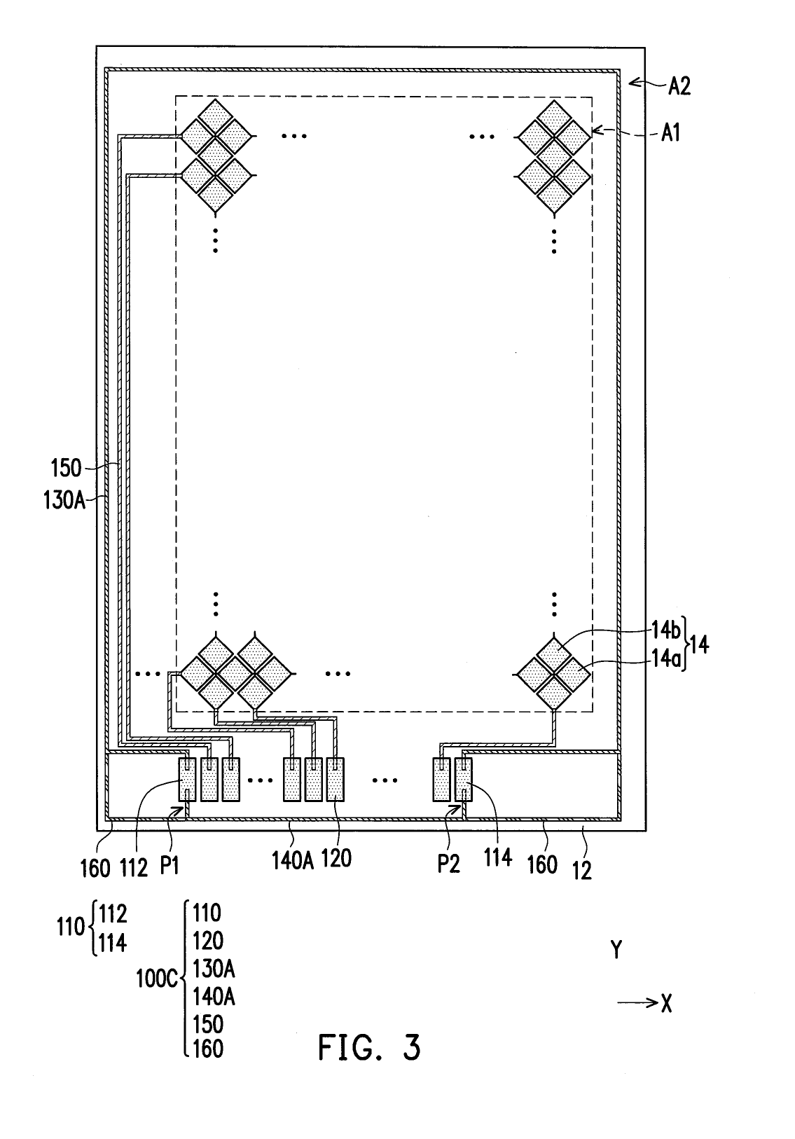

Referring to FIG. 3, a peripheral circuit structure 100C of the present embodiment has a structure similar to the peripheral circuit structure 100A of FIG. 1. The difference between the two embodiments mainly lies in the peripheral circuit structure 100C of the present embodiment further including a fourth trace 160 connected between the first trace 130A and the second trace 140A. Besides, a material of the fourth trace 160 may also be metal or metal alloy with good conductivity as the same as the first trace 130A, the second trace 140A and the third traces 150.

In the present embodiment, currents accumulated on the first ground pad 112 (or the second ground pad 114) may be transmitted out through the first trace 130A, the second trace 140A and the fourth trace 160. In other words, by increasing paths of the currents flowing through the first ground pad 112 and the second ground pad 114 in the present embodiment, the currents accumulated where the ground pads and the traces are connected may be effectively transmitted out. Thus, the capability of the peripheral circuit structure 100C for resisting the ESD may be improved, such that the reliability of an IC, a display panel or a touch panel applying the peripheral circuit structure 100B may be improved.

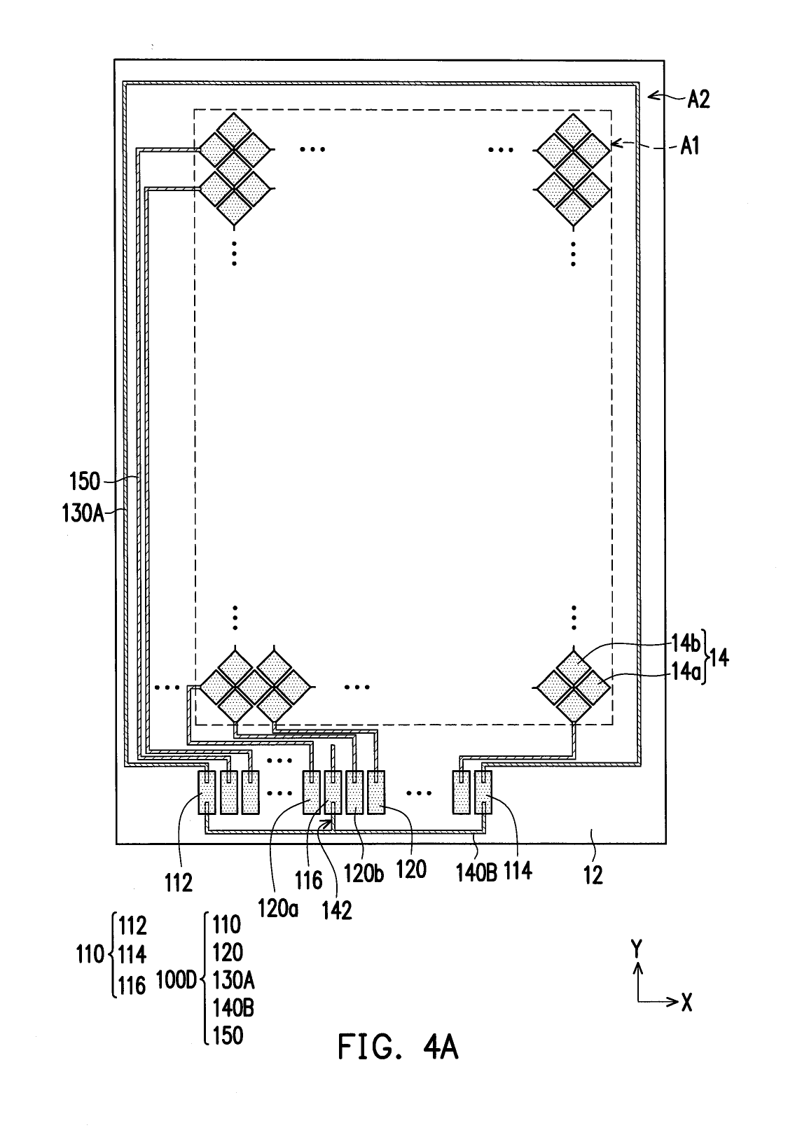

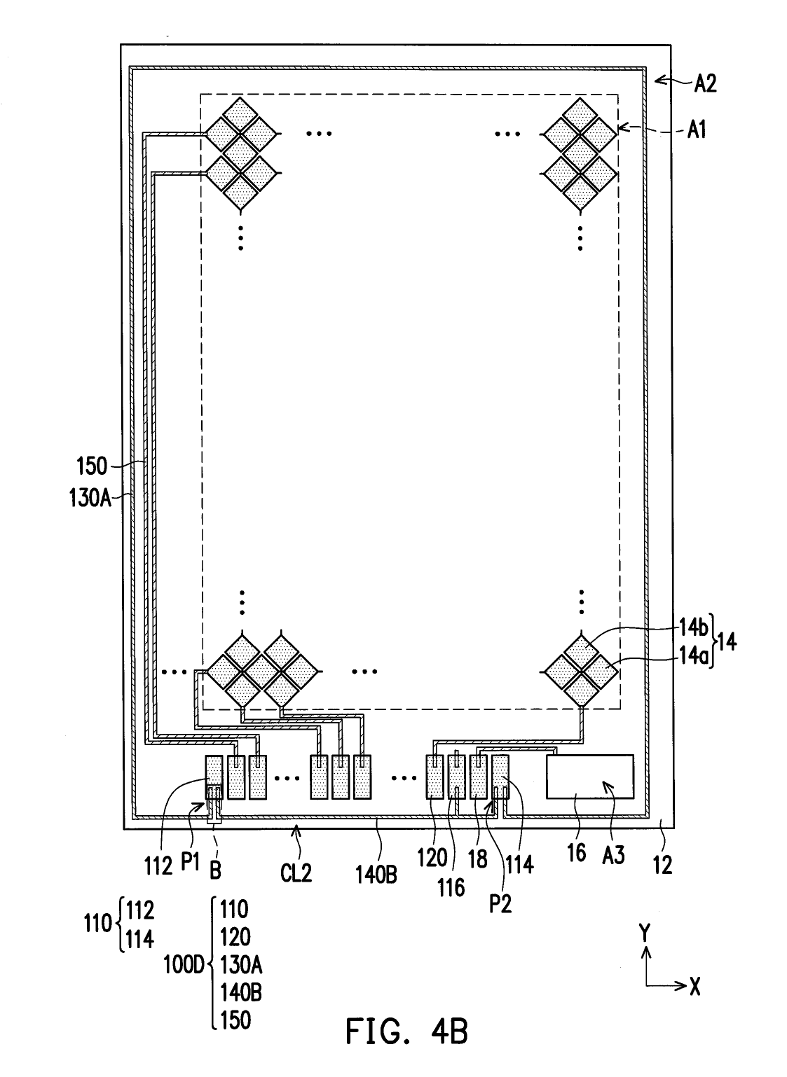

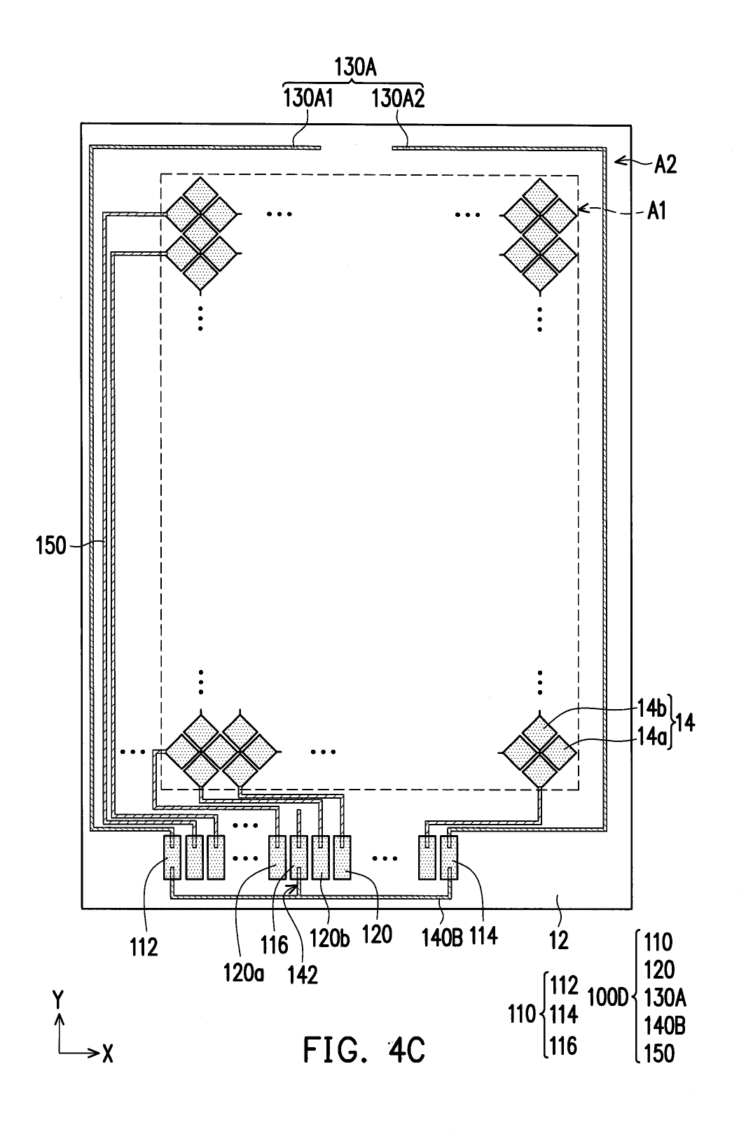

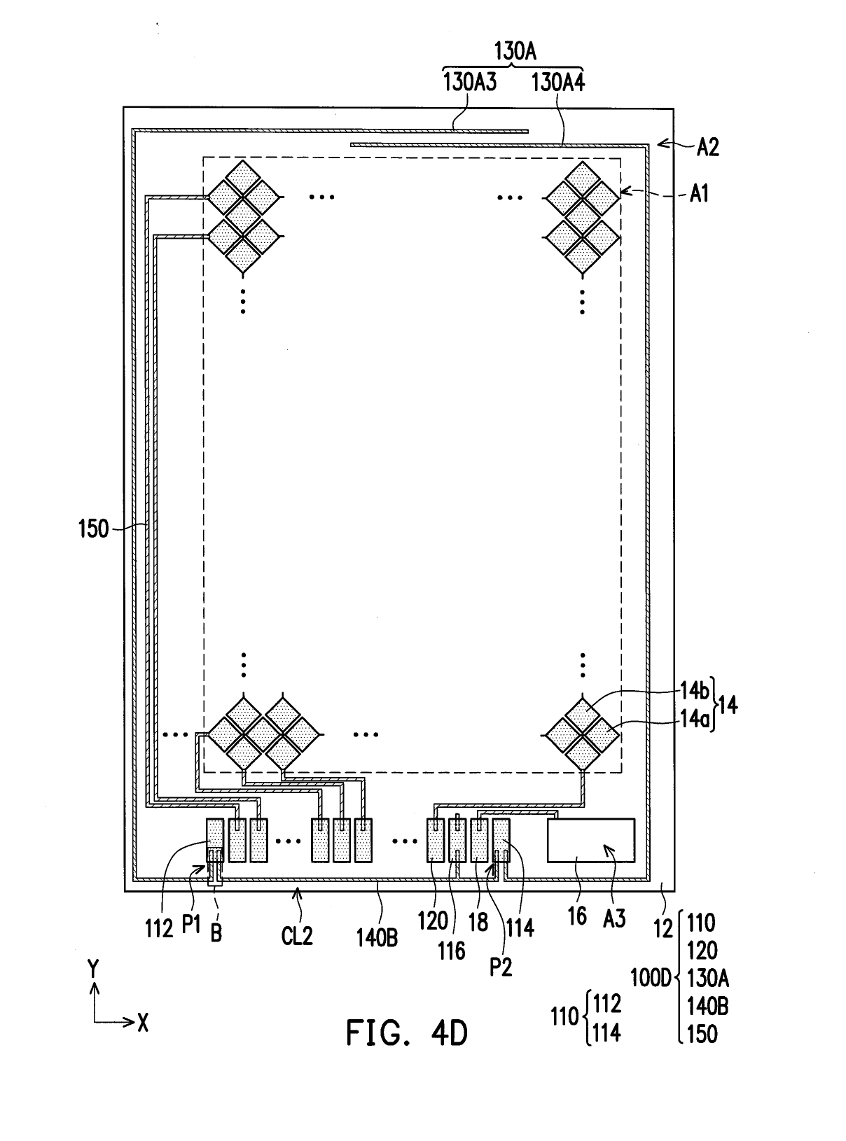

Referring to FIG. 4A, a peripheral circuit structure 100D of the present embodiment has a structure similar to the peripheral circuit structure 100A of FIG. 1. The difference between the two embodiments mainly lies in that the first pads 110 of the peripheral circuit structure 100D of the present embodiment further includes a third ground pad 116 located between two of the second pads 120a and 102b, and a second trace 140B is connected with the third ground pad 116.

In detail, the third ground pad 116 may be, for example, a ground pad located between the second pad 120a electrically connected with the first sensing string 14a and the second pad 120b electrically connected with the second sensing string 14b. In addition, the second trace 140B further has a protrusion portion 142, and the second trace 140B is connected with the third ground pad 116 via the protrusion portion 142.

Additionally, referring to FIG. 4B, the third ground pad 116 may also be a ground pad which separates the third pad 18 connected to the peripheral element 16 from other second pads 120.

In the embodiments of FIG. 4A and FIG. 4B, with the increase of the amount of the traces electrically with the grounds (including the first ground pad 112, the second ground pad 114 and the third ground pad 116), the paths of currents flowing through the first ground pad 112 and the second ground pad 114 may be increased to effectively transmit out the currents accumulated where the ground pads and the traces are connected. Thus, the capability of the peripheral circuit structure 100D for resisting the ESD may be improved, which contributes to improving the reliability of an IC, a display panel or a touch panel applying the peripheral circuit structure 100D. In detail, when a large amount of currents flow through the third ground pad 116, the second trace 140B and the protrusion portion 142 thereof may contribute to effectively transmitting out the currents accumulated on the third ground pad 116 to avoid the third ground pad 116 and the pads adjacent thereto being damaged by the electrostatic discharging. For example, the second trace 140B and the protrusion portion 142 thereof particularly contribute to effectively avoiding the second pads 120a and 120b being damaged by the electrostatic in the embodiment of FIG. 4A and to avoiding the third pad 18 being damaged by the electrostatic in the embodiment of the FIG. 4B. Further, it is to be mentioned that the number of the third ground pads is not limited, and if the number of the third ground pads is plural, the plurality of third ground pads may be entirely or partially connected to the second trace.

In FIG. 4C, the first trace 130A can be separated into discontinuous parts, e.g. a first part 130A1 and a second part 130A2. In addition, the first trace 130A shown in FIG. 4D can be separated into discontinuous parts, e.g. a first part 130A3 and a second part 130A4, wherein a portion of the first part 130A3 and a portion of the second part 130A4 are adjacent to each other to form a dual track-like pattern as shown in the top portion of FIG. 4D. In other words, the portion of the first part 130A3 and the portion of the second part 130A4 interlace with one another.

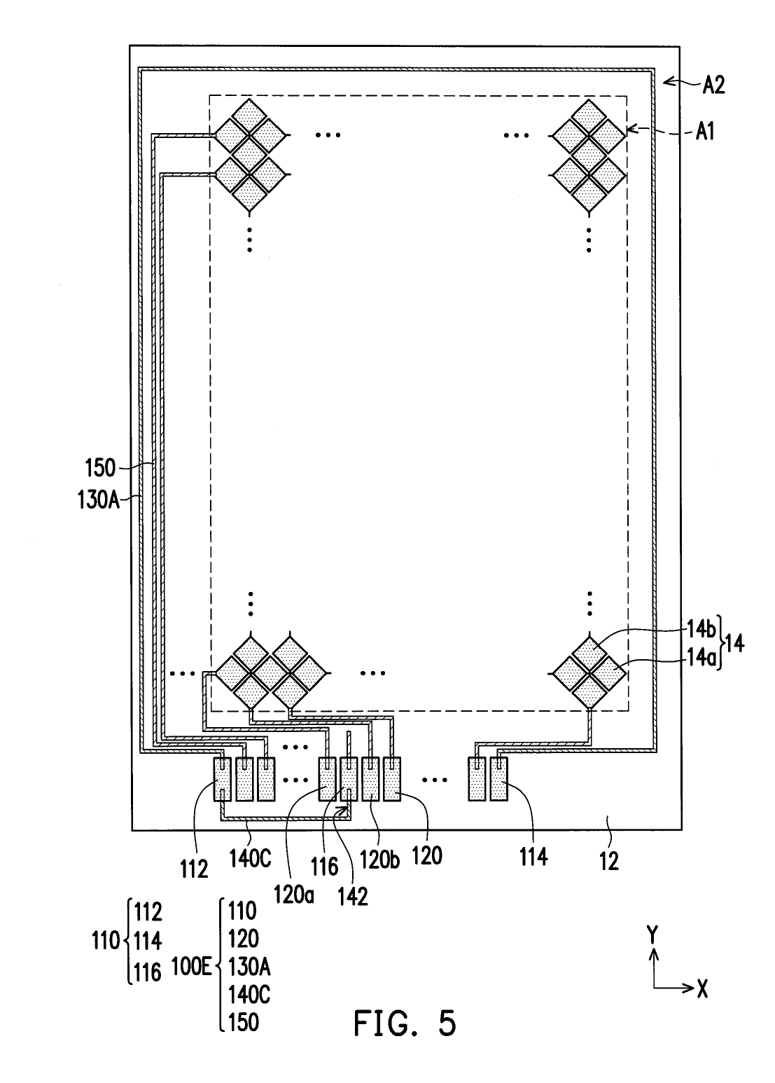

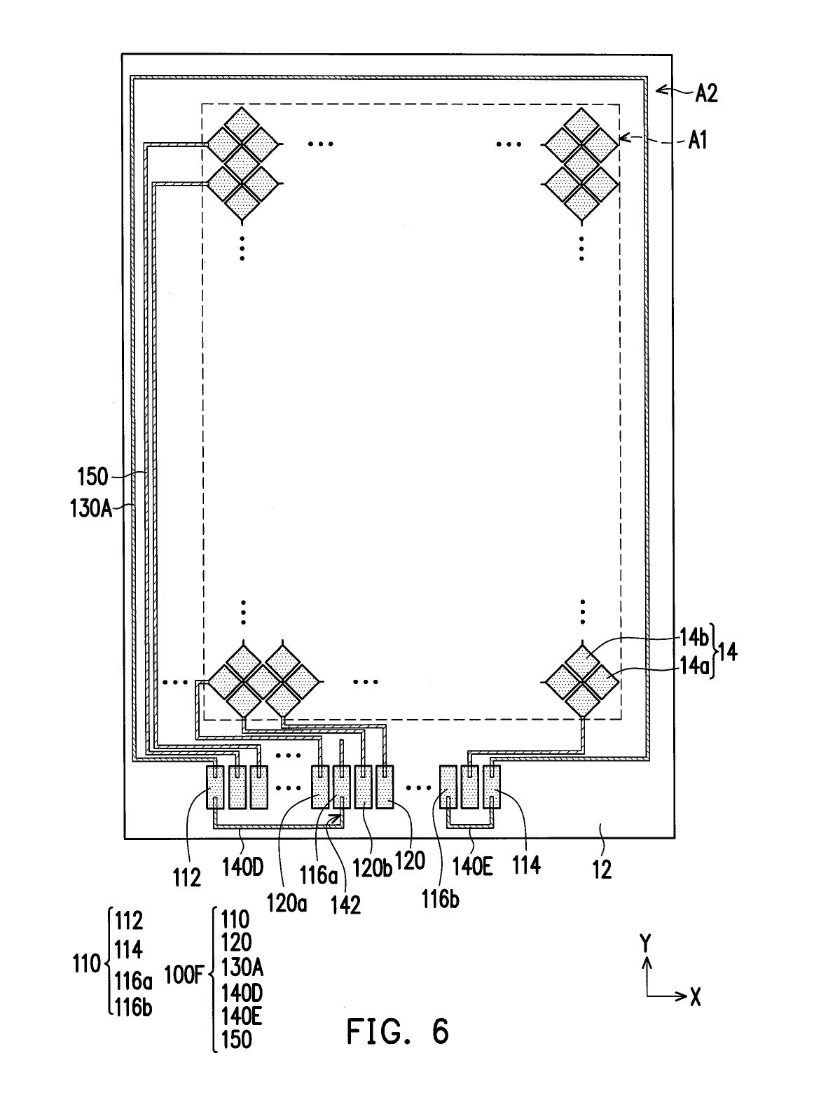

In the above-described embodiments, various types of implementations of the closed loop formed by the second trace, the first trace, the first ground pad and the second ground pad are illustrated. However, the present invention is not intent to limit that the second trace, the first trace, the first ground pad and the second ground pad have to form a closed loop. In other words, an open loop may also be formed by the aforementioned elements, which will be illustrated with reference to FIG. 5 and FIG. 6 hereinafter.

Referring to FIG. 5, a peripheral circuit structure 100E of the present embodiment has a structure similar to the peripheral circuit structure 100D of FIG. 4. The difference between the two embodiments mainly lies in that in the present embodiment, one end of a second trace 140C of the peripheral circuit structure 100E is connected to the third ground pad 116, while the other end is connected to the first ground pad 112. However, the present invention is not limited thereto. In other embodiments that are not shown, the other end of the second trace 140C may also be connected with the second ground pad 114. In other words, the other end of the second trace 140C may be connected with either one of the first ground pad 112 and second ground pad 114.

Referring to FIG. 6, a peripheral circuit structure 100F of the present embodiment has a structure similar to the peripheral circuit structure 100E of FIG. 5. The difference between the two embodiments mainly lies in the peripheral circuit structure 100F of the present embodiment further including third ground pads 116a and 116b and second traces 140D and 140E. Therein, one end of the second trace 140D is connected with the third ground pad 116a while the other end is connected with the first ground pad 112, and one end of the second trace 140E is connected with the third ground pad 116b while the other end is connected with the first ground pad 114.

In the embodiments of FIG. 5 and FIG. 6, with the increase of the amount of paths of currents flowing through the ground pads (including the first ground pad 112, the second ground pad 114 and the third ground pad 116), the currents accumulated where the ground pads and the traces are connected may be effectively transmitted out. Thus, the capability of the peripheral circuit structures 100E and 100F for resisting the ESD may be improved, which contributes to improving the reliability of an IC, a display panel or a touch panel applying the peripheral circuit structures 100E and 100F. In detail, when a large amount of currents flow through the third ground pads 116, 116a and 116b, the second traces 140C, 140D and 140E may contribute to effectively transmitting out the currents accumulated on the third ground pads 116, 116a and 116b to avoid the third ground pads 116, 116a and 116b and the pads adjacent thereto being damaged by the electrostatic discharging effect.

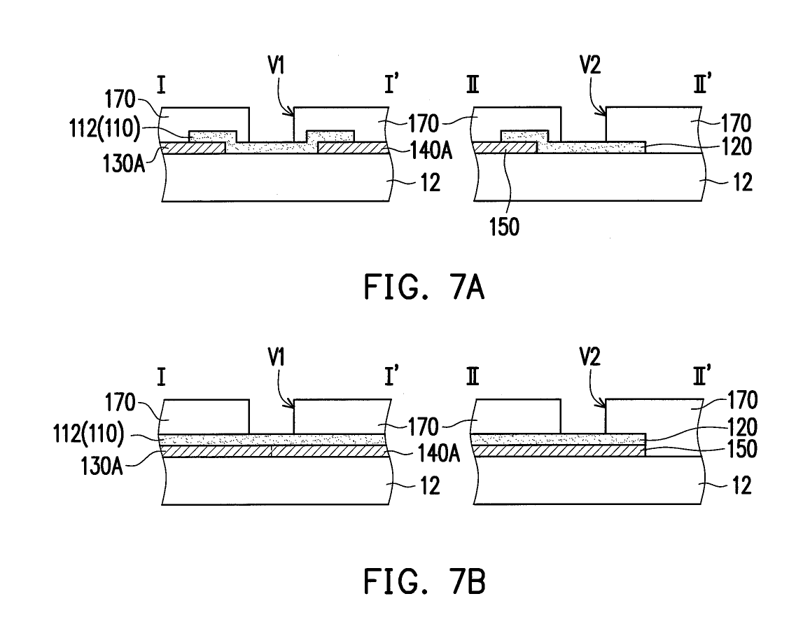

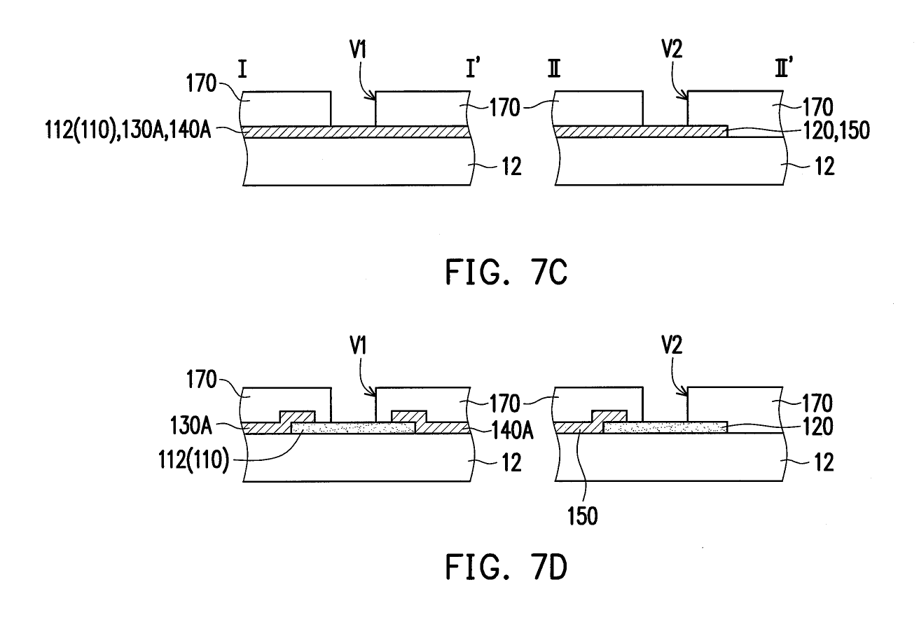

Hereinafter, with reference to FIG. 7A through FIG. 7D, the electrical connection manners of the first trace and the second trace with the first pads as well as the electrical connection manners of the third traces with the second pads will be further illustrated. FIG. 7A through FIG. 7D illustrate four types of connection modes of traces and pads. FIG. 7A through FIG. 7D are section schematic views along lines I-I′ and II-II' in FIG. 1 according to different embodiments, and herein the elements which are the same as or similar to those in FIG. 1 are labeled by the same numerals or symbols.

Referring to FIG. 7A, the peripheral circuit structure may further includes an insulation layer 170. In the present embodiment, the insulation layer 170 covers the first trace 130A, the second trace 140A, the third trace 150, the first pad 110 and the second pad 120 and has a plurality of openings V1 and V2. The openings V1 and V2 respectively expose a partial area of the first pad 110 and a partial area of the second pad 120. Specifically, in the present embodiment, the opening V1 exposes an area of the first pad 110, which does not overlap the first trace 130A or the second trace 140A, while the opening V2 exposes an area of the second pads 120, which does not overlap the third trace 150, for example. In detail, the first trace 130A and the second trace 140A of the present embodiment respectively extend to a place between the first pad 110 and the substrate 12, while the third trace 150 extends to a place between the second pad 120 and the substrate 12, for example, but the present invention is not limited thereto.

Referring to FIG. 7B, the first trace 130A and the second trace 140A may extend to the place between the first pad 110 and the substrate 12, and the first trace 130A and the second trace 140A may be connected with each other, for example. Additionally, the third trace 150 may extend to the place between the second pad 120 and the substrate 12, and one end of the third trace 150 is aligned with a terminal of the second pad 120, which is adjacent to an edge of the substrate 12, for example.

Further, referring to FIG. 7C, a material of the first pad 110 and the second pad 120 may be metal or metal alloy, likewise. Thus, the first pad 110, the second pad 120, the first trace 130A, the second trace 140A and the third trace 150 may be simultaneously manufactured.

Moreover, referring to FIG. 7D, the first trace 130A and the second trace 140A may extend from the substrate 12 to a top of the first pad 110, while the third trace 150 may extend from the substrate 12 to a top of the second pad 120. Besides, the insulation layer 170 at least covers the first trace 130A, the second trace 140A and the third trace 150 to avoid oxidation.

Additionally, the material of the first trace 130A, the second trace 140A and the third traces 150 is not limited to metal or metal alloy with good conductivity and may also be a transparent conductive material, such as metal oxide, while the material of the first pad 110 and the second pad 120 is not limited to metal oxide, and may also be the metal or metal alloy with good conductivity. Certainly, when the first pad 110, the second pads 120, the first trace 130A, the second trace 140A and the third traces 150 are simultaneously manufactured, the material thereof may likewise be metal or metal alloy or alternatively, a transparent conductive material, such as metal oxide.

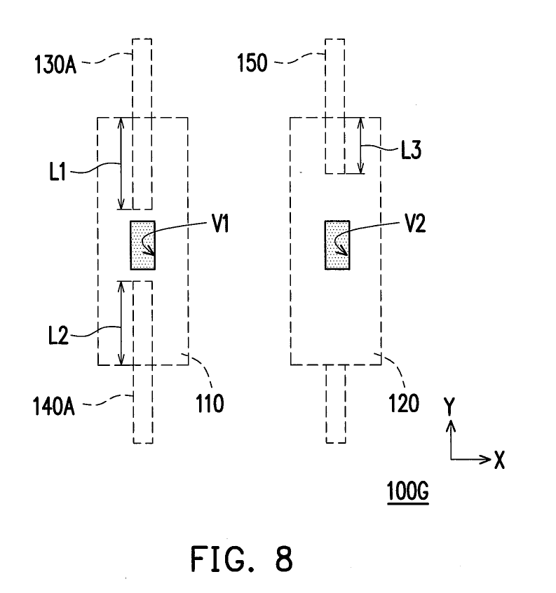

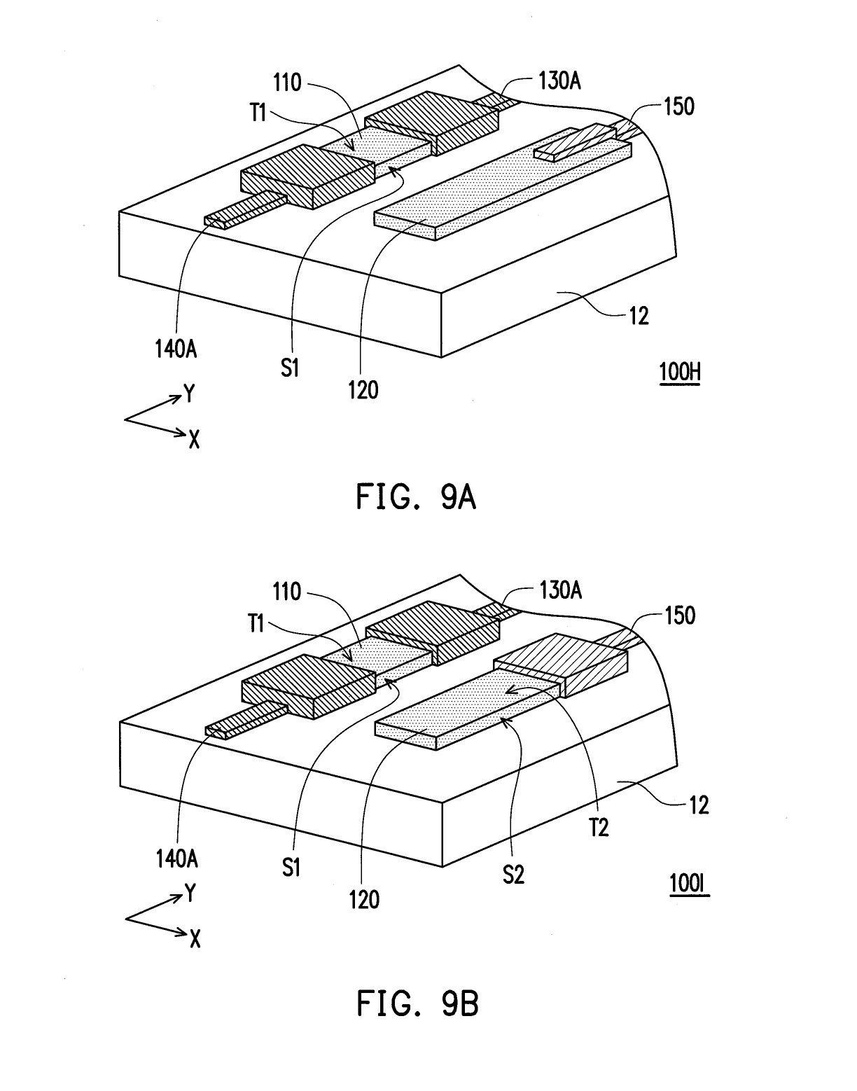

It is to be mentioned that in the previously described embodiments, the capability of the peripheral circuit structure for resisting the ESD may also be improved by increasing an area of the traces contacting the pads, which will be further illustrated with reference to FIG. 8, FIG. 9A and FIG. 9B. For the descriptive convenience, only one first pad 110 and one second pad 120 are shown in FIG. 8, FIG. 9A and FIG. 9B.

FIG. 8 is a partial schematic top view illustrating a peripheral circuit structure according to an embodiment of the present invention. Referring to FIG. 8, a peripheral circuit structure 100G of the present embodiment applies the peripheral circuit structure depicted in FIG. 7A. The difference between the two embodiments mainly lies in that the first trace 130A and the second trace 140A of the peripheral circuit structure 100G of the present embodiment respectively extend along the second direction Y to the place between the substrate 12 and the first pads 110 for a length L1 and for a length L2, while the third trace 150 extend along the second direction Y to the place between the substrate 12 and the second pads 120 for a length L3, and therein, the lengths L1 and L2 are larger than the length L3.

By increasing the lengths L1 and L2 of the first trace 130A and the second trace 140A respectively extending along the second direction Y to the places between the substrate 12 and the first pads 110, the capability of the currents flowing through the connection portion that are easily damaged by the electrostatic discharging effect in the present embodiment may be improved so as to avoid the peripheral circuit structure 100G being damages by the electrostatic discharging effect due instantaneous currents accumulated where the traces and the pads are connected. Accordingly, the peripheral circuit structure 100G of the present embodiment may have good capability for resisting the ESD, such that the reliability of an IC, a display panel or a touch panel applying the peripheral circuit structure 100G may be improved. In other embodiments that are not shown, by increasing the length L3 for the third trace 150 extending along the second direction Y to the place between the substrate 12 and the second pad 120, the capability of the currents flowing through the connection portion of the third trace 150 and the second pad 120 may also be improved, so as to avoid the peripheral circuit structure 100G being damaged by the electrostatic discharging effect due to the instantaneous current accumulated on the connection portion.

FIG. 9A is a partial schematic side view illustrating a peripheral circuit structure according to another embodiment of the present invention, and FIG. 9A is, for example, an implementation of FIG. 7B, where the insulation layer 170 previously depicted in FIG. 7B is omitted. Referring to FIG. 9A, each of the first trace 130A and the second trace 140A of a peripheral circuit structure 100H of the present embodiment extends from the substrate 12 to cover a top surface T1 of the first pad 110 and further cover a side wall S1 of the first pad 110.

In the present embodiment, beside contacting the top surface T1 of the first pad 110, the first trace 130A and the second trace 140A further contact the side wall S1 of the first pad 110. By increasing the area of the first trace 130A and the second trace 140A contacting the first pad 110, the current congestion occurring where the first trace 130A and the second trace 140A are connected with the first pad 110 may be mitigated so as to avoid the peripheral circuit structure 100H being damaged by the ESD due to the instantaneous currents accumulated at the connection places. Accordingly, the peripheral circuit structure 100H of the present embodiment may have good capability for resisting the ESD, such that the reliability of an IC, a display panel or a touch panel applying the peripheral circuit structure 100H may be improved.

FIG. 9B is a partial schematic side view illustrating a peripheral circuit structure according to still another embodiment of the present invention. Referring to FIG. 9B, a peripheral circuit structure 1001 of the present embodiment has a structure similar to the peripheral circuit structure 100H of FIG. 9A. The difference between the two embodiments mainly lies in that the third trace 150 of the peripheral circuit structure 1001 of the present embodiment extends to cover a top surface T2 of the second pad 120 and a side wall S2 of the second pad 120. Thus, the capability of the currents flowing through the connection portion may also be improved so as to avoid the peripheral circuit structure 1001 being damaged by the ESD due to the instantaneous current accumulated at the connection places. Accordingly, the peripheral circuit structure 1001 of the present embodiment may have good capability for resisting the ESD, such that the reliability of an IC, a display panel or a touch panel applying the peripheral circuit structure 100I may be improved.

Certainly, in the embodiments of FIG. 9A and FIG. 9B, the capability of the currents flowing through the connection portions may be improved by applying the concept proposed in the embodiment of FIG. 8. In brief, by increasing the lengths L1 and L2 of the first trace 130A and the second trace 140A extending along the second direction Y to the place between the substrate 12 and the first pad 110, the capability of the peripheral circuit structure 100H and 100I for resisting the ESD may also be improved.

Accordingly, in the present invention, the paths of the current flowing through the connection portions may be improved and the currents accumulated where the traces and the pads are connected may be effectively transmitted out by increasing the amount of the traces electrically connected with the first ground pad and the second ground pad. Thus, the capability of the peripheral circuit structure for resisting the ESD may be improved, such that the reliability of an IC, a display panel or a touch panel applying the peripheral circuit structure may also be improved.

Although the invention has been described with reference to the above embodiments, it will be apparent to one of the ordinary skill in the art that modifications to the described embodiment may be made without departing from the spirit of the invention. Accordingly, the scope of the invention will be defined by the attached claims not by the above detailed descriptions.

What is claimed is:

1. A peripheral circuit structure, disposed on a substrate comprising an element region and a peripheral circuit region, wherein the peripheral circuit structure is disposed in the peripheral circuit region, and a plurality of elements are disposed in the element region, the peripheral circuit structure comprising:
a plurality of first pads, comprising a first ground pad and a second ground pad;
a plurality of second pads, located between the first ground pad and the second ground pad;
a first trace, disposed around the element region and having two ends electrically connected with the first ground pad and the second ground pad respectively;
a second trace, located at a side of the second pads away from the element region, and having two ends electrically connected with the first ground pad and the second ground pad respectively so as to enable the second trace, the first trace, the first ground pad and the second ground pad to form a closed loop; and
a plurality of third traces, connected to the elements disposed in the element region, electrically connected with the second pads and located in a region demarcated by the closed loop.

2. The peripheral circuit structure according to claim 1, wherein the first trace and the second trace are respectively connected with two opposite ends of the first ground pad.

3. The peripheral circuit structure according to claim 1, wherein the first trace and the second trace are respectively connected with two opposite ends of the second ground pad.

4. The peripheral circuit structure according to claim 1, further comprising:
a fourth trace, connected between the first trace and the second trace.

5. The peripheral circuit structure according to claim 1, wherein both the first trace and the second trace are connected with one of the ends of the first ground pad away from the element region.

6. The peripheral circuit structure according to claim 1, wherein both the first trace and the second trace are connected with one of the ends of the second ground pad away from the element region.

7. The peripheral circuit structure according to claim 1, wherein the first pads further comprise a third ground pad located between two of the second pads, and the second trace is further connected with the third ground pad.

8. The peripheral circuit structure according to claim 1, wherein the first trace and the second trace extend from the substrate to cover a top of one of the first pads and a side wall of the one of the first pads.

9. The peripheral circuit structure according to claim 8, wherein at least one of the third traces extends from the substrate to cover a top of one of the second pads and a side wall of the one of the second pads.

10. The peripheral circuit structure according to claim 9, wherein lengths of the first trace and the second trace respectively covering the one of the first pads are larger than a length of the at least one of the third traces covering the one of the second pads.

11. The peripheral circuit structure according to claim 1, wherein the first trace and the second trace respectively extend to a place between the substrate and the one of the first pads, the at least one of the third traces extends to a place between the substrate and one of the second pads, and lengths of the first trace and the second trace respectively extending to the place between the substrate and the one of the first pads are larger than a length of the at least one of the third traces extending to the place between the substrate and the one of the second pads.

12. The peripheral circuit structure according to claim 1, wherein the first trace and the second trace respectively extend to a place between the substrate and one of the first pads, at least one of the third traces extends to a place between the substrate and one of the second pads, and the first trace is electrically connected with the second trace via the one of the first pads.

13. The peripheral circuit structure according to claim 1, wherein the first trace and the second trace respectively extend to a place between the substrate and one of the first pads, the first trace is directly connected with the second trace, at least one of the third traces extends to a place between the substrate and one of the second pads, and one end of the at least one of the third traces is aligned with a side of the one of the second pads adjacent to an edge of the substrate.

14. The peripheral circuit structure according to claim 1, wherein a material of the first pads, the second pads, the first trace, the second trace and the third traces comprises metal or metal alloy.

15. The peripheral circuit structure according to claim 1, further comprising:
an insulation layer, at least covering the first trace, the second trace and the third traces and having a plurality of openings, wherein the plurality of openings expose a partial area of each first pad and a partial area of each second pad.

16. The peripheral circuit structure according to claim 1, wherein the elements disposed in the element region comprise touch sensing elements or display elements.

17. The peripheral circuit structure according to claim 1, wherein when the first trace is connected with one end of one of the first pads away from the element region, the peripheral circuit structure further comprises a peripheral element located between the first trace and one of the third traces.

18. A peripheral circuit structure, disposed on a substrate comprising an element region and a peripheral circuit region surrounding the element region, wherein the peripheral circuit structure is disposed in the peripheral circuit region, and a plurality of elements are disposed in the element region, the peripheral circuit structure comprising:
a plurality of first pads, comprising a first ground pad, a second ground pad and at least one third ground pad located between the first ground pad and the second ground pad;
a plurality of second pads, located between the first ground pad and the second ground pad;
a first trace, disposed around the element region and having two ends electrically connected with the first ground pad and the second ground pad respectively;
a second trace, located at a side of each second pad away from the element region, and having one end connected with at least one of the third ground pads and the other end connected with one of the first ground pad and the second ground pad; and
a plurality of third traces, connected to the plurality of elements disposed in the element region and electrically connected with the plurality of second pads.

19. The peripheral circuit structure according to claim 18, wherein a material of the first pads, the second pads, the first traces, the second traces and the third traces comprises metal or metal alloy, and the first pads, the second pads, the first traces, the second traces and the third traces are simultaneously made.

20. A peripheral circuit structure disposed on a substrate, the substrate including an element region, and a peripheral circuit region located at a periphery of the element region, wherein the peripheral circuit structure is disposed on the peripheral circuit region and the element region is disposed with a plurality of elements, the peripheral circuit structure comprising:
at least one grounding pad;
a plurality of pads;
a first trace, surrounding at the periphery of the element region, wherein the first trace is electrically connected to the at least one grounding pad;
a second trace, electrically connected to the first trace and the at least one grounding pad; and
a plurality of third traces, connected to the elements in the element region and electrical connected to the pads.

21. The peripheral circuit structure according to claim 20, wherein the at least one grounding pad comprises a first grounding pad, a second grounding pad, and a third grounding pad, the first trace is electrically connected to at least one of the first grounding pad and the second grounding pad, and the second trace is electrically connected to the third grounding pad.

22. The peripheral circuit structure according to claim 21, wherein a material of the at least one grounding pad, the first trace, the second trace and the third trace comprises metal or metal alloy, and the at least one grounding pad, the first trace, the second trace and the third trace are simultaneously made.
